(19) United States
(12) Patent Application Publication
(10) Pub. No.: US 2014/0361785 A1
(43) Pub. Date: Dec. 11, 2014

(54) Fault Detection in Subsea Power Cables

(71) Applicant: Damir Radan, Sandnes (NO)

(72) Inventor: Damir Radan, Sandnes (NO)

(21) Appl. No.: 14/371,199

(22) PCT Filed: Jan. 25, 2013
(86) PCT No.: PCT/EP2013/051450

§ 371 Date: Jul. 9, 2014

(30) Foreign Application Priority Data
Jan. 31, 2012 (EP) 12000627.5

(51) Int. Cl. G01R 31/08; G01R 25/00

(52) U.S. Cl. CPC G01R 31/083; G01R 25/00; G01R 31/021
USPC 324/521; 324/512

(57) ABSTRACT

A method of detecting a fault in a subsea power cable or in a direct electric heating system including a subsea power cable is provided. Measuring points are distributed along the subsea power cable. The method includes measuring at each measuring point a current in the subsea power cable and comparing the currents measured at the different measuring points.

### CROSS-REFERENCE TO RELATED APPLICATIONS

The present patent document is a §371 nationalization of PCT Application Serial Number PCT/EP2013/051450, filed Jan. 25, 2013, designating the United States, which is hereby incorporated by reference, and this patent document also claims the benefit of EP 12000627.5, filed on Jan. 31, 2012, which is also hereby incorporated by reference.

### TECHNICAL FIELD

The embodiments relate to fault detection in subsea power cables.

### BACKGROUND

Recently, there has been an increasing interest in offshore hydrocarbon production. Hydrocarbon wells may be located many miles from shore sites and in water depths reaching down to several thousand meters. Subsea pipelines may be used for transporting hydrocarbons from an offshore well to a production vessel or to an onshore site, or may be used for transporting hydrocarbons between different onshore sites separated by an offshore section.

In deep waters, the water temperature is relatively low (e.g., between about −1 and +4° C.). When hydrocarbons are produced from a subsea well, the hydrocarbons may include a fraction of water, and furthermore will cool significantly upon reaching the seabed. This may lead to the formation of hydrates, which may be a combination of pressurized hydrocarbon gas with water. This combination may at low temperatures form a hydrate, which is a solid material. Hydrates may restrict the flow within a pipeline, or may even completely plug the pipeline.

Methods are known in the art which use chemicals for preventing hydrate formation. Another method that is more effective is the increase of the temperature of the pipeline, for example, by using direct electric heating (DEH). Such a DEH system is, for example, known from International Patent Publication No. WO 2004/111519, which uses a subsea single phase cable that is attached to two sides of a steel pipeline. A 50/60 Hz AC current is passed through the cable and the pipeline, and the pipeline is heated due to its electric resistance.

The power source may be located at an onshore location or on board of a production vessel, and an example of such power source is described in International Patent Publication No. WO 2010/031626. The pipeline section to be heated is a single phase load on the power supply arrangement.

The detection and finding of the location of a fault in medium to high voltage subsea cables, in particular, in subsea cables used in DEH systems may be difficult. A single phase subsea cable may be used to supply the power to heated pipeline section and may be connected to anodes. As the subsea direct electric heating is an impedance based load, the voltage on the cable approaches zero at the remote location.

Previous methods used so far may have limited accuracy for the detection of subsea faults at a far-remote location.

As the subsea direct electric heating is impedance based load, the voltage on the cable approaches zero at the remote location, which makes it difficult to use conventional methods of fault detection and location. A first conventional approach that may be used includes inverse time-current curves, where the current is different for different loads. In this approach, it is impractical to use one curve for each of the loads as, for example, 18 loads may be defined on existing DEH systems. Moreover, this approach may be inaccurate for far remote faults as the measured current in fault-less (normal) operations is relatively low (difficult to distinguish from a fault current).

A second approach includes impedance based protection where measured impedance Z=Voltage/Current is compared to find the reduction in impedance and thus the fault location proportional to load impedance. As the fault location may be located far away from the power source, a very small impedance change may only be detected. Errors in measuring equipment and calculations, and external influences to impedance value such as cable heating expansion may make this approach impractical to use, in particular, for the last 10% or 20% of the subsea cable length.

A third approach includes a detection method based on fiber-optics, such as described in International Patent Publication Nos. WO 2007/096775 and WO 2010/108976, which relate to the use of a fiber optical relay for DEH subsea cable protection, based on fiber-optics build inside the cable insulation. Yet the optical fibers are installed when the subsea cable is being produced, and the system is thus not suitable for existing installations. The system is also complex and expensive. If the fiber-optics get damaged or burned inside the cable, the detection system may not be used any longer and a new cable needs to be installed. This may pose a problem, as subsea cables are among the most expensive equipment.

Further, although fiber-optical detection methods may be very fast in fault detection, the detection methods may not be suitable for finding the fault location, as existing detection methods are all based on detecting changes in the cable temperature, assuming the increase of cable temperature will lead to burning of the cable. This assumption does not seem to be adequate, as the cable temperature may be different at locations at which the cable and the pipeline are buried in the ground, or at which the cable is not buried but cooled with surrounding seawater.

### SUMMARY AND DESCRIPTION

Accordingly, there is a need to obviate at least some of the drawbacks mentioned above and to provide an improved detection of faults in a subsea power cable.

The scope of the present invention is defined solely by the appended claims and is not affected to any degree by the statements within this summary. The present embodiments may obviate one or more of the drawbacks or limitations in the related art.

An embodiment provides a method of detecting a fault in a subsea power cable or in a direct electric heating (DEH) system including a subsea power cable, wherein measuring points are distributed along the subsea power cable, the method including measuring at each measuring point a current in the subsea power cable, comparing the currents measured at the different measuring points, and detecting the presence and the location of a fault in the subsea power cable or in the DEH system based on the comparison.

By making use of different measuring points, it may become possible to determine the location of the fault from a remote location, so that a repair of the subsea power cable or the DEH system is facilitated and made more efficient. Further, it may become possible to detect faults even at the far end of the subsea power cable or of a pipeline section that is heated via power from the subsea power cable in a DEH system.

In an embodiment, measuring the current at the measurement point includes measuring the phase angle of the current, and comparing the measured currents includes comparing the measured phase angles.

In an embodiment, the method further includes measuring at each measuring point a voltage in the subsea power cable and determining a phase angle (or difference) between the voltage and the current. By making use of a phase difference, the detection of faults at a far end of the protected zone of the subsea power cable is facilitated, in particular, since current magnitude may not change much during the occurrence of a fault at such position. Short circuit currents may be relatively low in case of a fault at a far end of the protected zone.

In an embodiment, the comparing of the phase angles for different measuring points may be done by comparing the phase differences between current and voltage, comparing current vectors, comparing polarities of the voltage measurements, or comparing directions derived for each measuring point from the current measurement, in particular, from phase angle of the current measurement. In these examples, the comparison of the currents of two measuring points is based on the phase angle of the current (compared to the voltage at the respective measuring point).

Different advantageous possibilities may thus be implemented for performing the current comparison. In particular, deriving a direction for each measuring point, (e.g., a direction pointing towards the fault), has the advantage that the evaluation of the fault location is facilitated.

The direction may point along the subsea power cable in one or the other direction and may be derived from a voltage polarity determined on the basis of the phase angle. In some embodiments, the derived direction may point along the subsea power cable in the direction of real power flow, and may be determined based on the current and voltage measurement at the respective measuring point. The derived directions may thus point to a sink constituted by the fault.

In an embodiment, measuring the current at the measurement point includes measuring the magnitude of the current, and comparing the measured currents includes comparing the measured current magnitudes.

In an embodiment, detecting the presence and the location of a fault in the subsea power cable or in the DEH system includes using a directional protection scheme based on the measured currents for detecting the location of the fault. The scheme may further be based on voltages measured at each measuring point, in particular, on a phase difference between current and voltage. Using a directional detection scheme may enhance the sensitivity for fault detection, in particular, for remote faults.

In an embodiment, the method further includes transmitting information on the measured current from a measurement point to another measurement point, in particular, to a neighbouring measurement point, and/or to a topside installation. The information may be transmitted to a fault detection unit, which may be a protection relay located at a measuring point, in particular, a master relay, a subsea control module, or a topside fault detection unit.

An embodiment provides a fault monitoring system for a subsea power cable or for a direct electric heating system including a subsea power cable. The fault monitoring system includes plural measuring units distributed along the subsea power cable and configured to measure a current in the subsea power cable at corresponding measuring points, and a fault detection unit configured to compare the current measurements of two or more measuring units and to detect the presence and the location of a fault in the subsea power cable or in the DEH system based on the comparison. Similar advantages as the ones outlined above with respect to the method may be achieved by such system.

In an embodiment, the fault monitoring system may further include a communication unit configured to transmit information on currents measured at different measuring points to the fault detection unit. Information on measured currents may include phase angle or phase difference, a voltage polarity derived from such phase angle or a direction derived from the current measurement, as set out above.

In an embodiment, the fault monitoring system may include a communication unit configured to transmit information on the presence and location of a fault to a topside installation. For example, at the topside installation, power to the subsea power cable may be cut in response to receiving such information.

In an embodiment, the fault detection unit is configured to be located subsea. By performing the evaluation of the measurements subsea, the system may be made more efficient and/or compact. In particular, the fault detection unit may be a protection relay located at a measuring point, in particular, a protection relay connected to a measuring unit, e.g., a master relay. In another embodiment, the fault detection unit may be a subsea module in communication with protection relays located at the measuring points. Such subsea module may be implemented in a subsea control module.

In another embodiment, the fault detection unit may be located at a topside installation.

In an embodiment, the fault detection unit is configured to compare the magnitude of the measured currents of the two or more measuring units. The current comparison may also be performed by comparing if a current was measured at all by the two or more measuring units. In case of a fault, measuring units and connected protection relays ‘downstream’ of the fault may no longer receive power. By detecting that these units do no longer provide information on current measurements (which may correspond to a current of zero), the fault detection unit may determine the presence and location of the fault. For the comparison, the fault detection unit may use information transmitted by the communication unit that may include current magnitude, on/off information about the measuring units, e.g., whether the measured current magnitude is above or below a given threshold.

In an embodiment, the fault detection unit is configured to compare the phase angle of the measured currents of the two or more measuring units.

As outlined above, comparing the phase angles does not need to be performed directly, but quantities or indicators derived from the phase angles may be compared. This may include comparing at least one of current vectors, directions derived from the phase angles (in particular, a direction pointing towards the fault, e.g., the direction of real power flow), or voltage polarity of voltages measured by the two or more measuring units. The magnitude of the respective measurements may also be considered. The respective quantities may be communicated by a communication unit from the respective measuring point to the fault detection unit. Communicated information on current measurements may for example include phase angle, current vector or derived direction.

In an embodiment, the fault detection unit is configured to detect the presence and location of a fault between two neighbouring measuring points if the direction derived at one measuring point points in one direction whereas the direction derived at the other measuring point points in a reverse direction. Both may for example point towards the fault. Detection of the fault location is thus facilitated.

In an embodiment, at each measuring point, a measuring unit, a protection relay and a communication unit are provided. The communication unit may be part of the protection relay.

In an embodiment, for each measuring point, the protection relay may be configured to perform a current and a voltage measurement using the respective measuring unit. The protection relay may further be configured to determine a direction on the basis of a phase difference between the measured current and voltage. As an example, the direction may point in the direction of real power flow. If a fault occurs upstream of a protection relay, the power flow at the respective measuring point may be reversed, leading to a change in polarity at a measuring voltage transformer of the measuring unit, which may be detected as a change in the phase difference (or phase angle) between voltage and current. The direction for this protection relay may thus be reversed, pointing towards the fault. The protection relay may further be configured to communicate the determined direction to the fault detection unit, e.g., by using the communication unit.

In an embodiment, the measuring unit includes a measuring current transformer mounted at the measuring point to the subsea power cable for measuring said current. The measuring unit may further include a measuring voltage transformer for performing a voltage measurement at the respective measuring point.

In an embodiment, the fault detection unit is configured to compare the current measured by a measuring unit with the current measured by neighboring measuring units.

In an embodiment, the fault detection unit is configured to detect the presence and location of a fault if the current vector at one measuring point points in reverse direction whereas the current vector measured at a neighboring measuring point points in forward direction.

In an embodiment, the fault monitoring system further includes an energy storage coupled to the subsea power cable in proximity to a remote end thereof, in particular, in proximity to a remote end of a pipeline section to be heated at which the subsea cable is electrically coupled to the pipeline section. If a fault occurs at the subsea power cable between measuring points, the measuring units and associated protection relays are enabled to measure a power flow from the energy storage towards the fault. This may make the determination of the fault location more precise. This may also provide operability for downstream protection relays after such fault. The energy storage may be configured to supply electric power to the subsea power cable when the subsea power cable is in a de-energized state, e.g., before providing the main power to the subsea power cable or after fault (e.g. after the main power supply to the subsea power cable was cut). Measurements downstream of the fault (as seen from the main power source) may thus be enabled.

In an embodiment, a communication unit is provided for each measuring unit, wherein the communication units are configured to communicate with each other using wireless communication or using a communication line, in particular, a fiber optic communication line or power line communication via the subsea cable. One unit or each communication unit may be configured to communicate with a topside installation, at which, e.g., the fault detection unit or a protection device for disabling the main power supply to the subsea power cable may located, or to communicate with a subsea control module in which the fault detection unit may be located.

In certain embodiments, the fault monitoring system may furthermore be configured so as to perform any of the above outlined methods. Similarly, the above outlined methods may be performed on embodiments of the fault monitoring system.

It is to be understood that the features mentioned above and those yet to be explained below may be used not only in the respective combinations indicated, but also in other combinations or in isolation. In particular, the features of the embodiments described above and those described hereinafter may be combined with each other unless noted to the contrary.

### BRIEF DESCRIPTION OF THE DRAWINGS

FIG. 1 depicts an embodiment of a schematic diagram with possible locations of fault occurrences in a subsea power cable of a DEH system.

FIG. 2 is a schematic block diagram of a fault monitoring system in accordance with an embodiment.

FIG. 3 is a schematic block diagram of a fault monitoring system in accordance with an embodiment.

FIG. 4 depicts a schematic block diagram of a fault monitoring system in accordance with an embodiment.

FIG. 5 is a schematic block diagram of a fault monitoring system in accordance with an embodiment.

FIG. 6 is a schematic block diagram of a fault monitoring system in accordance with an embodiment.

### DETAILED DESCRIPTION

In the following, embodiments are described in detail with reference to the accompanying drawings. It is to be understood that the following description of embodiments is given only for the purpose of illustration and is not to be taken in a limiting sense.

It is noted that the drawings are schematic representations only, and elements in the drawings are not necessarily to scale with each other. Also, the coupling of physical or functional units as depicted in the drawings and described hereinafter does not necessarily need to be a direct connection or coupling, but may also be an indirect connection or coupling, e.g., a connection or a coupling with one or more additional intervening elements. A skilled person will further appreciate that the physical or functional units illustrated and described herein with respect to the different embodiments do not necessarily need to be implemented as physically separate units. One or more physical or functional blocks or units may be implemented in a common circuit, circuit element or unit, while other physical or functional blocks or units depicted may be implemented in separate circuits, circuit elements or units.

Although the following description is given with respect to a subsea power cable of a direct electrical heating (DEH) system, the embodiments are equally applicable to other types of subsea power cables, e.g., to subsea power cables used to transport electric power to a subsea installation, e.g., to a subsea power grid or to transport electric power in such subsea power grid or between components of a subsea installation. Other uses are certainly conceivable.

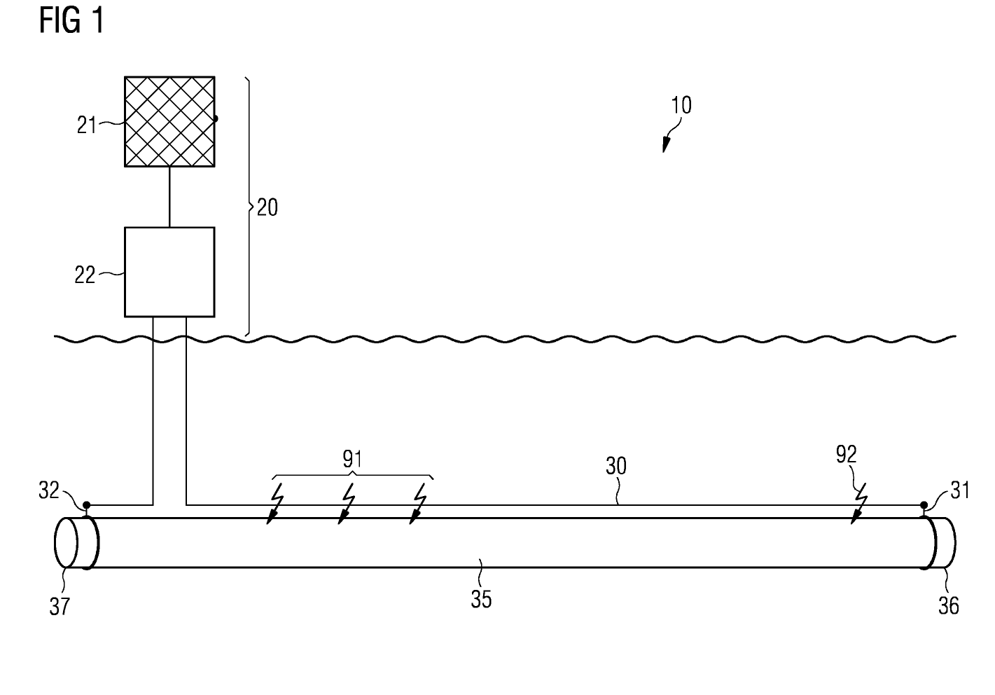

FIG. 1 depicts a DEH system 10. The DEH system 10 includes a power system 21 that provides a main power source for direct electrical heating. Power system 21 may include a power grid, a generator or the like. The DEH system 10 further includes a power supply system 22 for a subsea load. Power supply system 22 may include at least one controller for controlling the power flow into the subsea power cable as well as at least one protective device (e.g., at least one circuit breaker).

Power system 21 and the power supply system 22 for a subsea load are both included in the topside installation 20. Note that in other configurations, power supply system 22 may be located at a subsea installation, and may be part of a subsea power grid.

The DEH system 10 is provided for heating several pipeline sections of a subsea pipeline for transporting hydrocarbons. In the example of FIG. 1, an exemplary pipeline section 35 is depicted. The power supply system 22 is coupled to both ends 36, 37 of the pipeline section 35. The subsea power cable 30 is part of said coupling and is used to transport electric energy to the far end 36 of the pipeline section 35. In operation, single phase AC voltage is applied to both ends 36, 37 of the pipeline section. Due to the conductivity and impedance of the pipeline section, current is conducted within the pipeline section 35 and heats the pipeline section, (thus the name ‘direct electrical heating’).

In operation, faults may occur along the subsea power cable 91. Such faults may be located closed to the power supply system 22 (and thus to the main power source for the direct electrical heating), like faults 91, or the faults may be located further away (far-remote faults), like the fault 92. Faults include ground faults as well as faults resulting from an electrical contact between the subsea power cable 30 and the pipeline section 35 (of course other than the electrical connections provided at ends 36, 37). As may be seen, fault 92 is relatively close to the electric connection provided at end 36 of the pipeline section. Accordingly, the voltage drop caused by such fault is small and the fault will be difficult to detect.

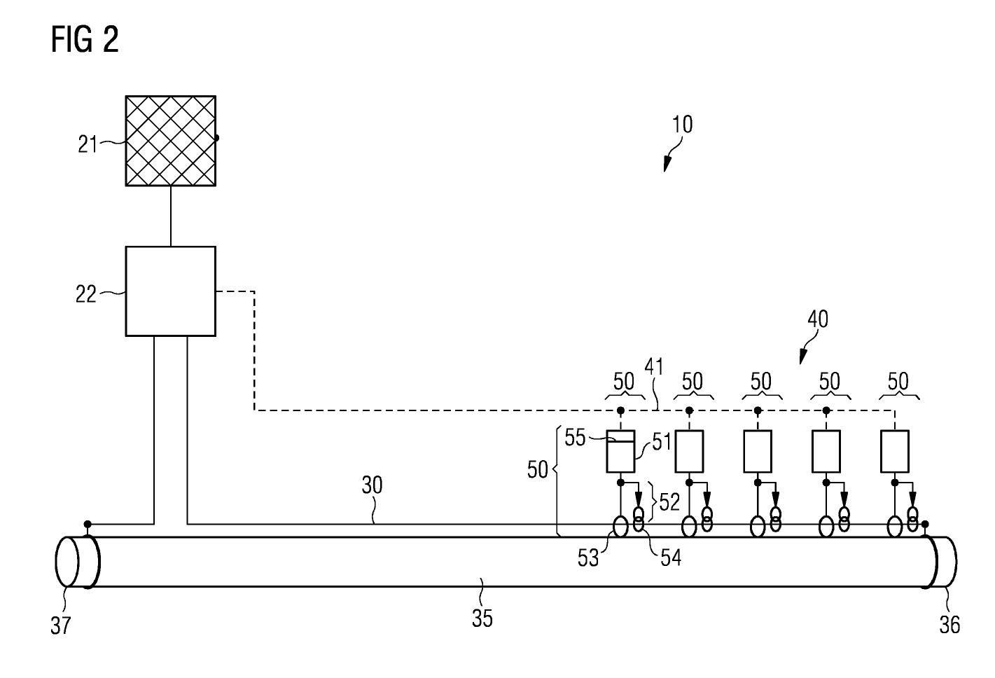

The problem of subsea cable fault detection and location presented above may be solved by using fault monitoring system 40 in accordance with an embodiment depicted in FIG. 2, where a number of measuring transformers 53, 54 are located along the subsea power cable 30, in particular, along the far remote part of the subsea power cable 30. The current transformers 53 are located at so called measuring points to measure current inside the subsea power cable 30. The current transformers 53 are used to compare the currents in the individual segments between these measuring points.

Furthermore, a protection relay 51 and a communication unit 55, which may be part of the protection relay 51, are provided at each measuring point. The measuring current transformer 53 is considered to be part of a measuring unit 52. The communication unit 55, the protection relay 51 and the measuring unit 52 form a protection device 50. Such protection device is provided at several measuring points along the subsea power cable, in particular, along its remote part in proximity to the remote end 36 of the pipeline section 35.

By the communication unit 55, the protection devices 50, in particular, the protection relays 51 may communicate with each other and/or with another device of e.g. a subsea installation or a topside installation using a communication link or line 41. Such communication line 41 may be provided by wireless communication, by optical communication (e.g. using a fiber optic cable) or by power line communication, e.g. using the subsea cable 30 as a power line, or using a dedicated power line provided for powering the protection relays 51.

In some embodiments, measuring unit 52 includes only a measuring current transformer 53. In other embodiments, the measuring unit 52 may furthermore include a measuring voltage transformer 54.

A segment is hereinafter defined as a segment of the subsea power cable located between two measuring points, e.g., between two measuring devices 50.

The following are embodiments of detection methods that may be used with this arrangement. In one embodiment, the detection method includes a current comparison between segments that is based on monitoring of the current flow interruption after the last measuring point that will signify the fault location towards the right hand side of the power supply to the subsea power cable 30. The fault may be located towards the far end 36 of the pipeline section in the segment adjacent to the last protection relay 51 that measures a current in the subsea power cable 30 by the respective current transformer 53.

In another embodiment, the detection method includes a directional logical protection method for DEH that is based on direction of vector currents (phasors) in individual segments. This protection scheme may operate when the DEH system is off-load and may be used prior or after energizing DEH. Location of a fault in a segment will lead to a change in voltage polarity for the protection relays 51 located between the fault and the far end 36 of the pipeline section 35. Electric power may for this purpose be injected at the far end of the subsea power cable 30 to enable a voltage measurement at such locations.

Note that apart from the subsea power cable of a DEH system, the system and method of the present embodiments may be used for detecting faults on any type of subsea power cable.

Several measuring points are located along the far-remote part of the subsea power cable 30 on the direct electric heating single phase system 10, as depicted in FIG. 2. Each measuring point is equipped with a measuring current transformer 53 and/or a measuring voltage transformer 54. Both the current transformer 53 and measuring voltage transformer 54 may be used for current vector (magnitude and phase angle) measurement.

Measuring transformers 53, 54 may be fixed along the subsea cable, and are connected to the individual digital protection relays 51, which may be provided in a subsea box. Measuring transformers 53, 54 may be mechanically protected against water and may be placed either directly around the subsea power cable 30 or inside special mechanical protection tool. Such mechanical protection tools are available for providing mechanical protection to the subsea power cable.

Power supply for each protection relay 51 or protection device 50 may be provided by use of small transformers that may take power from the subsea power cable 30. The power consumption of protection relay 51 or protection device 50 may be lower than 100 Watts, and thus relatively small. As the current in the subsea power cable 30 may be several hundred amperes, (e.g. between 700 and 1600 A), and the transported power may range from 2 MW to 20 MW or more, it may be unlikely that the current used to power the protection devices 50 (relays 51) may be sensed as a current leak, as the power used for the protection relays 51 will be lower than 0.005% of the DEH load (which may be lower than the measuring accuracy).

Each relay protection device may communicate between each other using wireless communication or communication via a communication line, e.g., a fiber optic cable or the above mentioned power line communication. The communication between devices will allow the detection of the fault and the sending of a signal to the topside installation, where this signal may trip the circuit breaker (e.g., included in power supply system 22) of the subsea load (here the pipeline section 35). In certain embodiments, the communication may be wireless. In other embodiments, the communication may be through an optical communication, e.g., via fiber optic cable, since fiber optic cable is relatively resistant against electromagnetic disturbances.

Regarding the evaluation of the measurements, several implementations are conceivable. Each protection relay 51 may have be configured to perform a processing of measured data, e.g., deriving current magnitude, deriving a phase angle or current vector from measured current or voltage, determining current magnitude, determining voltage magnitude, determining voltage polarity (based on the phase angle of the current), determining the direction of real power flow (e.g., from the phase angle between voltage and current), determining a direction in which the fault is located (which may correspond to the direction of real power flow) and the like. All such information is directly derived from the current measurement and may thus be considered to represent the current. Comparing currents may thus involve the comparison of any of the above outlined derived quantities. Each of these quantities may be communicated to a fault detection unit that determines the presence and location of a fault from the received data.

The fault detection unit receives the information, compares the currents measured at the different measuring points and determines the presence and location of a fault (if such is present). As mentioned above, the comparison may include the comparison of any of the above outlined quantities, e.g., current magnitude, current phase angle, a polarity derived from the phase angle, a direction derived from the phase angle and the like.

The fault detection unit may be implemented in several ways. In some embodiments, the fault detection unit may be located subsea. The fault detection unit may be implemented by a respective functionality in each of the protection relays 51. In other embodiments, one protection relay 51 may act as a master relay and may implement the fault detection unit. This master relay may be the protection relay located closest to the main power source 22. In further embodiments, the fault detection unit may be implemented in a subsea control module (SCM), which may be provided with such additional functionality.

In these embodiments, the fault detection unit may be located in a subsea enclosure. The fault detection unit is further configured to communicate with a topside installation (e.g., topside installation 20) so that the unit can, in case of the detection of a fault, transmit a signal for triggering circuit breakers or other protective equipment associated with the subsea power cable 30. In other embodiments, the fault detection unit may communicate with protective equipment located at the subsea installation, such as a subsea switchgear, for cutting the power to a faulty subsea power cable 30. Further damage to the subsea power cable 30 and connected equipment may thus be prevented.

In other embodiments, the fault detection unit may be located at the topside installation, e.g., in the power supply system 22. The protection relays 51 may, via the respective communication units 55, transmit information on the measured currents (e.g., the above outlined quantities) to the fault detection unit via the communication link 41. The fault detection unit may the directly issue a trip command to a circuit breaker of the power supply system 22 for disconnecting the subsea power cable 30 in case of the occurrence of a fault.

An implementation of the fault detection unit is within a protection relay 51 acting as a master relay. In the following description and in the figures, it is assumed that the fault detection unit is implemented in the protection relay 51, in particular, in the one closest to the power supply system 22. The fault detection unit is configured to calculate the vector of currents based on a current measurement and voltage polarization, and may be contained in a subsea canister and sealed against the ingress of sea water. The explanations given herein after are equally applicable to embodiments in which the fault detection unit is implemented in a SCM or at a topside installation.

One way of detecting the presence and location of a fault that may be used by the fault detection unit is the current comparison between segments.

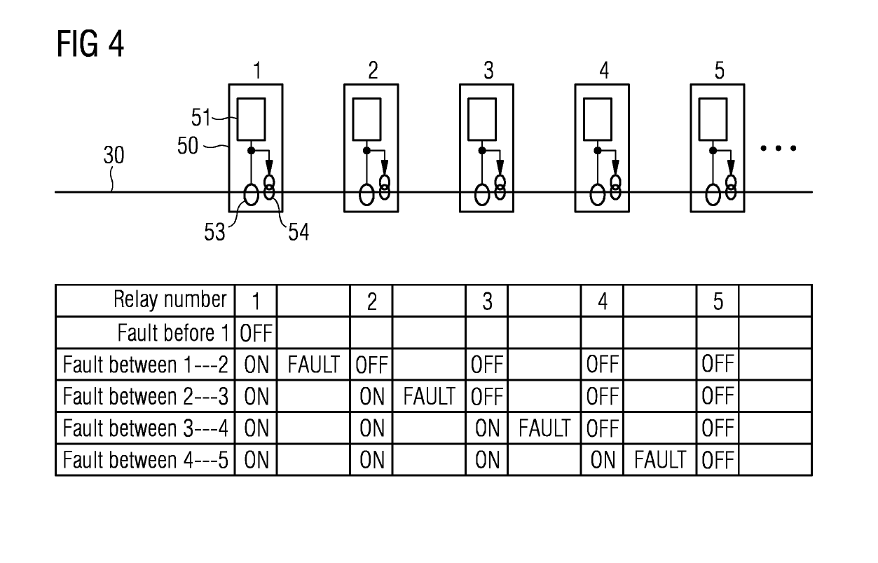

The logic is based on comparison of load currents in normal operations, not necessarily short-circuit currents as short circuit current may be very low when a far-remote fault occurs. The current at a single measuring location point in the system is compared by the fault evaluation unit with a neighboring measuring point. If the current is lower than the current on the other measuring point or zero, the fault is contained to the right hand side of the first location. The determination of fault location may be based on the logic matrix depicted in FIG. 4. Moreover, if the current on all relays to the right hand side was reported lower than on the first relay to the left, the fault is contained in the right hand segment adjacent to the first relay.

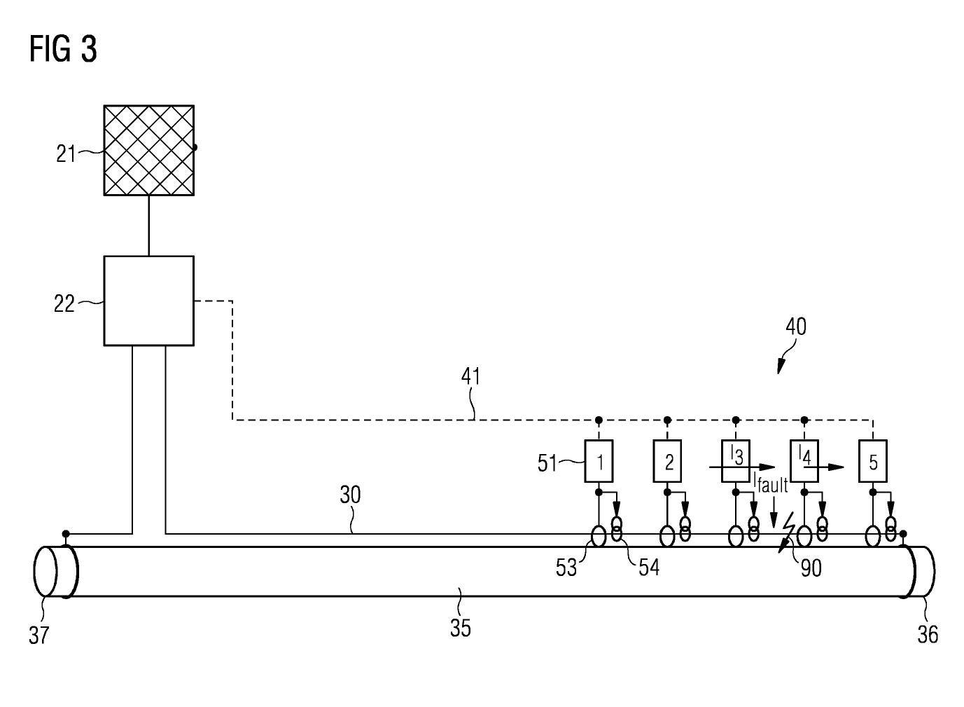

In FIGS. 3 and 4, five protection relays 51 are provided, and are designated by numerals 1-5. In the example of FIG. 3, relay 3 measures a current I₃ while relay 4 measures a current I₄. In case a fault occurs in the segment between relays 3 and 4, a fault current I_{fault} will exist. The current measured by I₄ is then:

I₄=I₃−I_{fault}. (1)

Thus, the fault location may be detected by the respective current measurements and may be determined by the fault evaluation unit, which may receive the current magnitude measured by the respective relay, an indication that the current magnitude is below or above a threshold, or an indication that no current was measured at all (e.g., be receiving no communication from the respective relay, e.g., the relay is ‘off’ and all current flows via the fault (fully bolted fault), so that the power supply to downstream relays is interrupted). In case of normal operation, I₄ equals I₃ and I_{fault}=0.

FIG. 4 depicts an example of a logic for full bolted faults when all current is consumed by the fault and interrupted to other devices and supply. FIG. 4 further depicts a table including a fault detection logic matrix that may be used to detect the fault location based on the current measurements.

The table in FIG. 4 illustrates how the fault location is detected based on information whether the respective protection relay is ‘on’ or ‘off’, e.g., measures a current or is cut off from the power supply. This may of course be implemented similarly by using current magnitudes, with a drop in current magnitude between two measuring point indicating the fault location, e.g., the faulty segment.

The protection relays 51 may have self-monitoring functions that may run self-diagnostics and detect any faults inside the respective relay, so there is no need for an assumption that the relay failed to work (hidden failure inside relay) when an relay state ‘off’ is detected. Such assumption may thus not be used in the protection logic illustrated in FIG. 4.

Another way of detecting the presence and location of a fault that may be used by the fault detection unit is the directional logic method, which may also be used with DEH systems and subsea power cables.

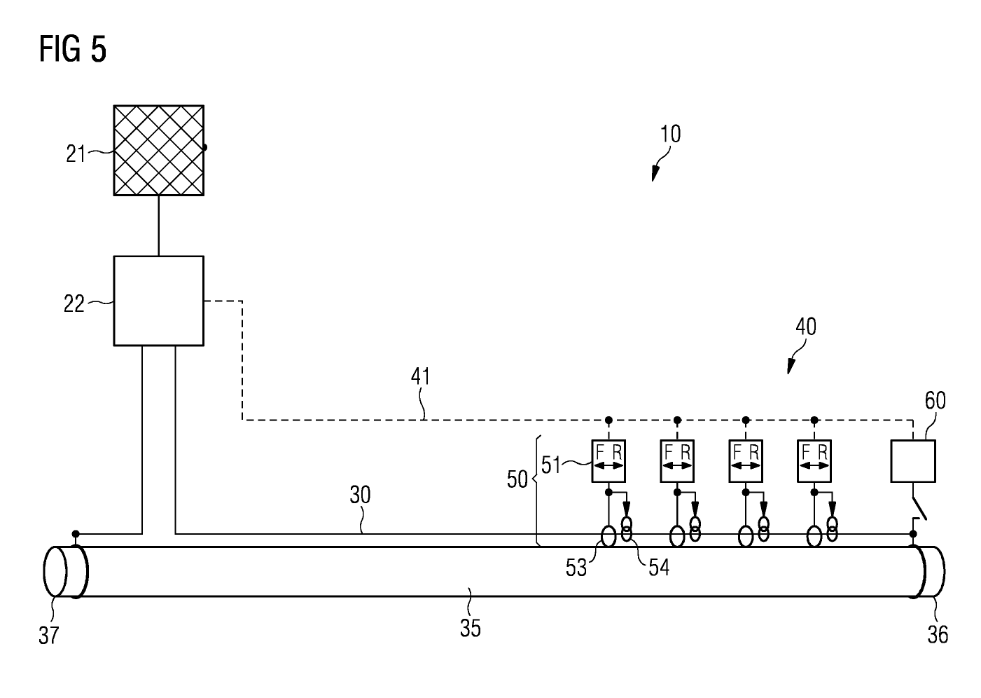

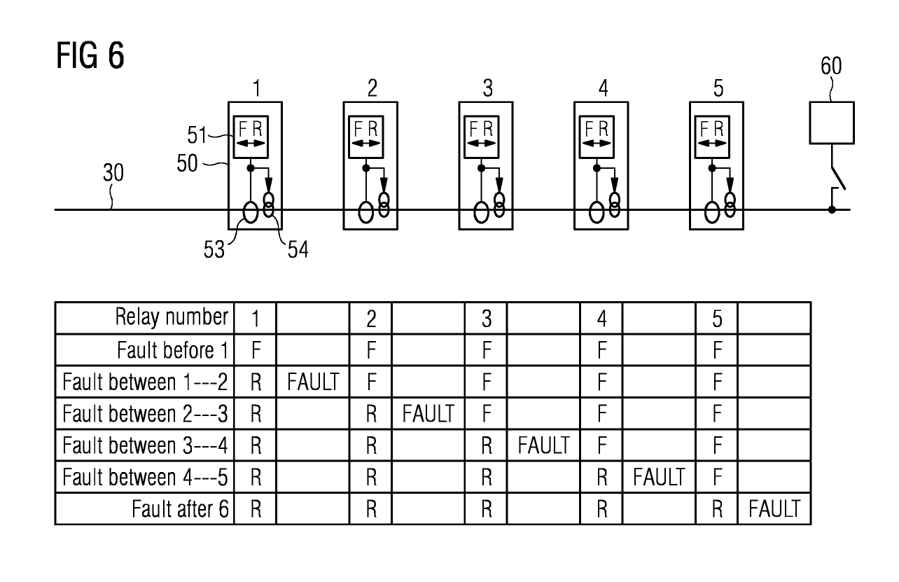

The detection method is based on the principle that even if the current magnitudes do not change much during the fault, the current phase angles will change. The protection relays may be programmed such that the protection relays determine a direction from the phase angle that points towards the direction of the fault (in FIGS. 5 and 6 termed Reverse (R) or Forward (F)). This detection method is herein termed “directional protection.”

In a particular embodiment, each protection relay 51 may be configured to derive from a current may voltage measurement by measuring unit 52 to determine a direction of real power flow in the subsea power cable. In normal operation, real power flows away from the power supply 22 and towards the load (direction (R) in FIGS. 5 and 6), here to the pipeline section 35. The direction of real power flow may be determined by the protection relay from the phase angle between voltage and current. If a fault occurs, the fault will constitute a sink towards that the real power will flow. Thus, the relays ‘upstream’ of the fault still determine a direction R towards the load and the fault, whereas the downstream relays determine an opposite direction F, which is pointing to the fault yet away from the load.

The logic is based on a comparison of load currents or test currents, not necessarily short-circuit currents as short circuit currents may be very low when a far-remote fault occurs. The current vector at a single measuring point location in the system will be compared with neighboring measuring point. The fault is detected if one relay points Reverse (R) and neighboring relay points Forward (F). This is illustrated in the Table logic presented in FIG. 6.

The logic will work if there is separate power source at each side of the fault, or pipeline. DEH applications may include a single power supply for a pipeline section. The power supply may be located close to the middle or to an end of the pipeline section. In any case, there will be at least one remote end of the pipeline section that in FIGS. 5 and 6 is the right hand end 36. A fault may thus interrupt the power supply to a part of the subsea power cable leading to the remote end. At measuring point located at this part of the subsea power cable 30, no current and phase angle measurements may thus be performed.

However, this problem may be overcome. A low voltage energy storage 60, in form of e.g., battery, capacitor or similar, may be placed on the other side of the subsea cable, as presented in FIG. 5. This energy storage 60 may be connected after the occurrence of a fault after that the downstream part of the subsea power cable is de-energized (wherein “downstream” refers to a direction away from the power supply and towards the load). The energy storage thus allows a current and voltage measurement by the relays downstream of the fault. The energy storage 60 may include an inverter, or the like, for generating an AC output for the purpose of performing the measurement.

Also, after the occurrence of a fault, the upstream relays may no longer be able to make measurements, in particular, when the power to the subsea power cable is cut. The protection relays 51 may thus include a memory in which the memory stores past measurements, phase angle, current vector, and/or the derived direction, (e.g., R or F). The relays upstream of the fault will thus have stored the direction Reverse (R) before the system was tripped (disconnected). After the system is de-energized, it is possible to switch-on the low voltage energy storage 60 that may supply electric power to the subsea cable from the other side of the cable and thus, the downstream relay may determine the measuring points at which the current phasor or derived direction points in Forward (F) direction. Accordingly, the direction F or R may be determined for each measuring point. Based on the logic scheme presented in FIG. 6, the location of the fault may be derived.

Other implementations of how the directional protection may be implemented are also conceivable, such as, for example, the determining of a current vector or current phasor at each measuring point and the comparing of the current vectors and current phasors at the fault detection unit, or the like.

The embodiments described herein have several advantages. Faults may be detected with high speed and high sensitivity. The sensitivity to faults is high since load currents may be compared, not only short-circuit currents (I>, I>>, I>>>) as in conventional relay protection methods. A high sensitivity to faults is also achieved since the signal is always compared by comparing values of similar current and voltage amplitudes at measuring points (current and voltage transformers), so that differences are relatively easy to detect. A high reliability may be achieved since the detection of false faults is reduced, and may be eliminated. Another advantage is the relatively easy setting of the system and the possibility to estimate the fault location subsea.

It is to be understood that the elements and features recited in the appended claims may be combined in different ways to produce new claims that likewise fall within the scope of the present invention. Thus, whereas the dependent claims appended below depend from only a single independent or dependent claim, it is to be understood that these dependent claims may, alternatively, be made to depend in the alternative from any preceding or following claim, whether independent or dependent, and that such new combinations are to be understood as forming a part of the present specification.

While the present invention has been described above by reference to various embodiments, it may be understood that many changes and modifications may be made to the described embodiments. It is therefore intended that the foregoing description be regarded as illustrative rather than limiting, and that it be understood that all equivalents and/or combinations of embodiments are intended to be included in this description.

1. A method of detecting a fault in a subsea power cable (30) or in a direct electric heating (DEH) system (10) comprising a subsea power cable (30), wherein measuring points are distributed along the subsea power cable, the method comprising the steps of
measuring at each measuring point a current in the subsea power cable (30);
comparing the currents measured at the different measuring points; and
detecting the presence and the location of a fault in the subsea power cable or in the DEH system based on the comparison.

2. The method according to claim 1, wherein measuring the current at the measurement point comprises measuring the phase angle of the current, and wherein the step of comparing the measured currents comprises comparing the measured phase angles.

3. The method according to claim 1 or 2, wherein the method further comprises measuring at each measuring point a voltage in the subsea power cable and determining a phase difference between the voltage and the current.

4. The method according to claim 3, wherein the step of comparing the measured currents comprises at least one of comparing phase angle, comparing current vectors, comparing polarities of the voltage measurements, or comparing directions derived for each measuring point from the current measurements.

5. The method according to any of the preceding claims, wherein measuring the current at the measurement point comprises measuring the magnitude of the current, and wherein the step of comparing the measured currents comprises comparing the measured current magnitudes.

6. The method according to any of the preceding claims, wherein the step of detecting the presence and the location of a fault in the subsea power cable or in the DEH system comprises using a directional protection scheme based on the measured currents for detecting the location of the fault.

7. The method according to any of the preceding claims, further comprising the step of transmitting information on the measured current from a measurement point to another measurement point, in particular to a neighbouring measurement point, and/or to a topside installation.

8. A fault monitoring system (40) for a subsea power cable (30) or for a direct electric heating system (10) comprising a subsea power cable (30), the fault monitoring system comprising:
plural measuring units (52) distributed along the subsea power cable and adapted to measure a current in the subsea power cable (30) at corresponding measuring points; and
a fault detection unit adapted to compare the current measurements of two or more measuring units (52) and to detect the presence and the location of a fault in the subsea power cable or in the DEH system based on the comparison.

9. The fault monitoring system according to claim 8, further comprising a communication unit (55) adapted to transmit information on currents measured at different measuring points to the fault detection unit.

10. The fault monitoring system according to claim 8 or 9, wherein the fault monitoring system (40) comprises a communication unit (55) adapted to transmit information on the presence and location of a fault to a topside installation (20).

11. The fault monitoring system according to any of claims 8-10, wherein the fault detection unit is adapted to be located subsea.

12. The fault monitoring system according to any of claims 8-11, wherein the fault detection unit is a protection relay (51) located at a measuring point or a subsea module in communication with protection relays (51) located at the measuring points.

13. The fault monitoring system according to claim 8 or 9, wherein the fault detection unit is located at a topside installation (20).

14. The fault monitoring system according to any of claims 8-13, wherein the fault detection unit is adapted to compare the current measurements by comparing the magnitude of the measured currents of the two or more measuring units or by comparing if a current was measured at all by the two or more measuring units.

15. The fault monitoring system according to any of claims 8-14, wherein the fault detection unit is adapted to compare the current measurements by comparing phase angles of the measured currents of the two or more measuring units (52), in particular by comparing at least one of current vectors, directions derived from the phase angles, or voltage polarity of voltages measured by the two or more measuring units.

16. The fault monitoring system according to claim 15, wherein the fault detection unit is adapted to detect the presence and location of a fault between two neighbouring measuring points if the direction derived at one measuring point points in one direction whereas the direction derived at the other measuring point points in a reverse direction.

17. The fault monitoring system according to any of claims 8-17, wherein at each measuring point, a measuring unit (52), a protection relay (51) and a communication unit (55) are provided.

18. The fault monitoring system according to claim 17, wherein for each measuring point, the protection relay is adapted to perform a current and a voltage measurement using the respective measuring unit and to determine a direction on the basis of a phase difference between the measured current and voltage.

19. The fault monitoring system according to any of claims 8-18, wherein the measuring unit comprises a measuring current transformer (53) mounted at the measuring point to the subsea power cable, and preferably further comprises a measuring voltage transformer (54).

20. The fault monitoring system according to any of claims 8-19, wherein the fault detection unit is adapted to compare the current measured by a measuring unit (52) with the current measured by one or more neighbouring measuring unit.

21. The fault monitoring system according to any of claims 8-20, wherein the fault monitoring system further comprises an energy storage (60) coupled to the subsea power cable (30) in proximity to a remote end thereof, in particular in proximity to a remote end (36) of a pipeline section (35) to be heated at which the subsea power cable (30) is electrically coupled to the pipeline section (35).

22. The fault monitoring system according to any of claims 8-21, wherein a communication unit (55) is provided at each measuring point, wherein the communication units are adapted to communicate with each other using wireless communication or using a communication line, in particular a fibre optic communication line or power line communication via the subsea cable (30).

23. DEH system (10) comprising a fault monitoring system (40) according to any of claims 8-22.
